(19) United States
(12) Patent Application Publication
(10) Pub. No.: US 2016/0211689 A1
(43) Pub. Date: Jul. 21, 2016

(54) CHARGING APPARATUS, POWER SUPPLY COMPONENT AND RACK MODULE

(71) Applicant: AVer Information Inc., New Taipei City (TW)

(72) Inventors: Yu-Jung WANG, New Taipei City (TW); Chih-Hung CHENG, New Taipei City (TW)

(21) Appl. No.: 14/798,894

(22) Filed: Jul. 14, 2015

(30) Foreign Application Priority Data
Jan. 19, 2015 (TW) 104101716

(51) Int. Cl. H02J 7/00; H05K 7/18; A47B 96/04

(52) U.S. Cl. CPC H02J 7/0045; A47B 96/04; H05K 7/18

(57) ABSTRACT

A charging apparatus is for charging an electronic device and accommodating an electronic device and a power cable connected to the electronic device, the power cable has a transformer. The charging apparatus includes a case body, a partition member and a power supply component. The case body has an accommodation space. The accommodation space has a main accommodating zone, a power supply zone and a sub-accommodating zone. The power supply zone is located above the main accommodating zone. The sub-accommodating zone is located on a side of the main accommodating zone. The sub-accommodating zone is for accommodating the transformer. The partition member is disposed in the main accommodating zone. The main accommodating zone is divided into a plurality of housing spaces by the partition member divides for accommodating the electronic device. The power supply component is disposed in the power supply zone for being coupled to the power cable.

### CROSS-REFERENCE TO RELATED APPLICATIONS

This non-provisional application claims priority under 35 U.S.C. §119(a) on Patent Application No(s). 104101716 filed in Taiwan, R.O.C. on Jan. 19, 2015, the entire contents of which are hereby incorporated by reference.

### TECHNICAL FIELD

The present disclosure relates to a charging apparatus, a power supply component and a rack module, and more particularly to a charging apparatus for charging electronic devices.

### BACKGROUND

E-learning is the use of electronic educational technology in distance education in order to help people who are willing to study but unable to go to residential school. Accordingly, electronic devices are used for E-learning. For example, the electronic devices are notebook computers or tablet computers.

In addition, with the rapid development of the technology in recent years, E-learning is not limited to time or location, and there are lots of applications installed in the electronic devices to assist teaching. With respect to these advantages, E-learning has widely been applied in schools or cram schools.

Hence, manufacturers develop many kinds of charging apparatuses which are able to charge a large quantity of the electronic devices in schools or cram schools. For example, charging apparatuses are charging carts or charging cabinets. However, because the charging apparatuses accommodate lots of the electronic devices, power cables of the electronic devices are increased, causing the power cables to be tangled with each other. Furthermore, most of traditional charging apparatuses are designed for tablet computers users, and these are universal serial bus (USB) type, That is, these charging apparatuses are not designed for notebook computers which have power transformers as one of charging equipments. Thus, most of the traditional charging apparatuses do not have enough space exclusively designed for accommodating the transformers. When the power cables are placed into the charging apparatus, the power cables and the transformers are more likely to get tangled with the each other. Space of the charging apparatus for accommodating the electronic devices is occupied by these transformers, and thus it is hard for users to take or place the electronic devices. Even more, schools have to buy another charging apparatus which is larger in size for solving aforementioned problems.

### SUMMARY

One embodiment of the disclosure provides a charging apparatus for charging at least one electronic device and accommodating at least one electronic device and at least one power cable which is connected to the at least one electronic device. The power cable has at least one transformer. The charging apparatus includes a case body, at least one partition member and at least one power supply component. The case body has an accommodation space, and the accommodation space has a main accommodating zone, a power supply zone and at least one sub-accommodating zone. The power supply zone is located above the main accommodating zone, the at least one sub-accommodating zone is located on a side of the main accommodating zone, and the sub-accommodating zone is for accommodating the at least one transformer. The at least one partition member is disposed in the main accommodating zone, and the main accommodating zone is divided into a plurality of housing spaces by the at least one partition member. The plurality of housing spaces are for accommodating the at least one electronic device. The at least one power supply component is disposed in the power supply zone for being coupled to the at least one power cable.

Another embodiment of the disclosure provides a power supply component for being fixed on an object and charging at least one electronic device. The power supply component includes a power supply part and at least one locking part. The power supply part has a plurality of receptacles. The at least one locking part is disposed on the power supply part, and the at least one locking part has a first extension section and a second extension section. An extension direction of the first extension section and an extension direction of the second extension section are intersected to each other, and both the first extension section and the second extension section are located on two sides of two ends of the power supply part which are adjacent to each other, respectively. Each of the first extension section and the second extension section has a locking groove. The power supply component is locked to the object via the locking groove of the first extension section or the locking groove of the second extension section.

Yet another embodiment of the disclosure provides a rack module for being disposed on an object and accommodating at least one electronic device. The rack module includes a fixing seat and a plurality of partition members. The fixing seat is detachably disposed on the object. The plurality of partition members is detachably disposed on the fixing seat, a housing space being located between the partition members. The housing space is for accommodating the at least one electronic device.

### BRIEF DESCRIPTION OF THE DRAWINGS

FIG. 1 is a perspective view of a charging apparatus housing an electronic device, a power cable and a transformer according to an embodiment of the present disclosure.

FIG. 2 is a front view of the charging apparatus according to the embodiment of the present disclosure.

FIG. 3 is an explode view of the charging apparatus according to the embodiment of the present disclosure.

FIG. 4 is a schematic perspective view of a rack module according to the embodiment of the present disclosure.

FIG. 5A is a schematic perspective view of a power supply component disposed on the charging apparatus according to the embodiment of the present disclosure.

FIG. 5B is another schematic perspective view of the power supply component disposed on the charging apparatus according to the embodiment of the present disclosure.

FIG. 6 is a top view of the charging apparatus housing the power cable and the transformer according to the embodiment of the present disclosure.

FIG. 7A is an exploded view of the charging apparatus housing the power cable and the transformer when a lid is lifted according to the embodiment of the present disclosure.

FIG. 7B is another exploded view of the charging apparatus housing the electronic device, the power cable and the transformer according to the embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

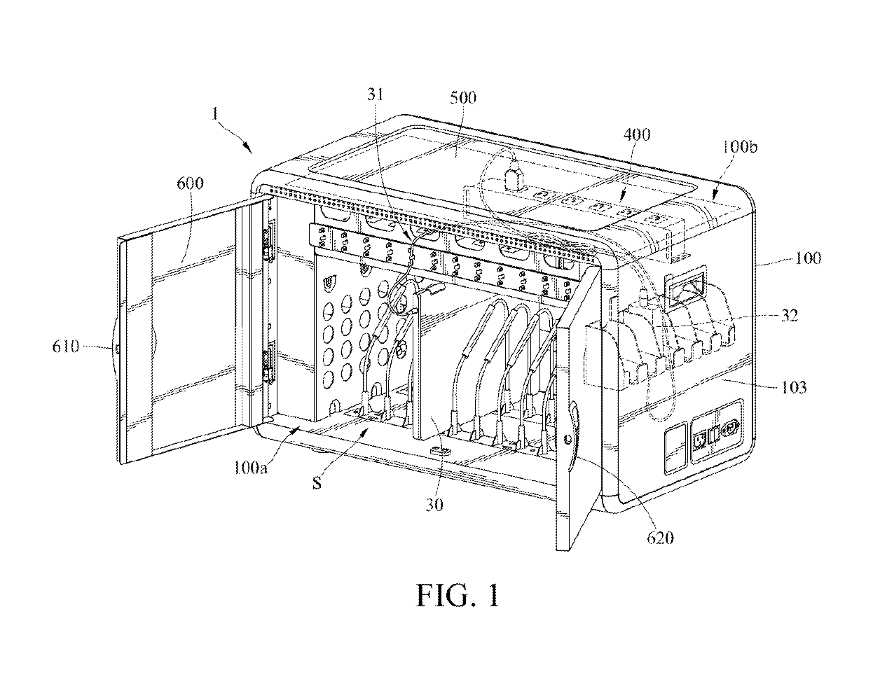

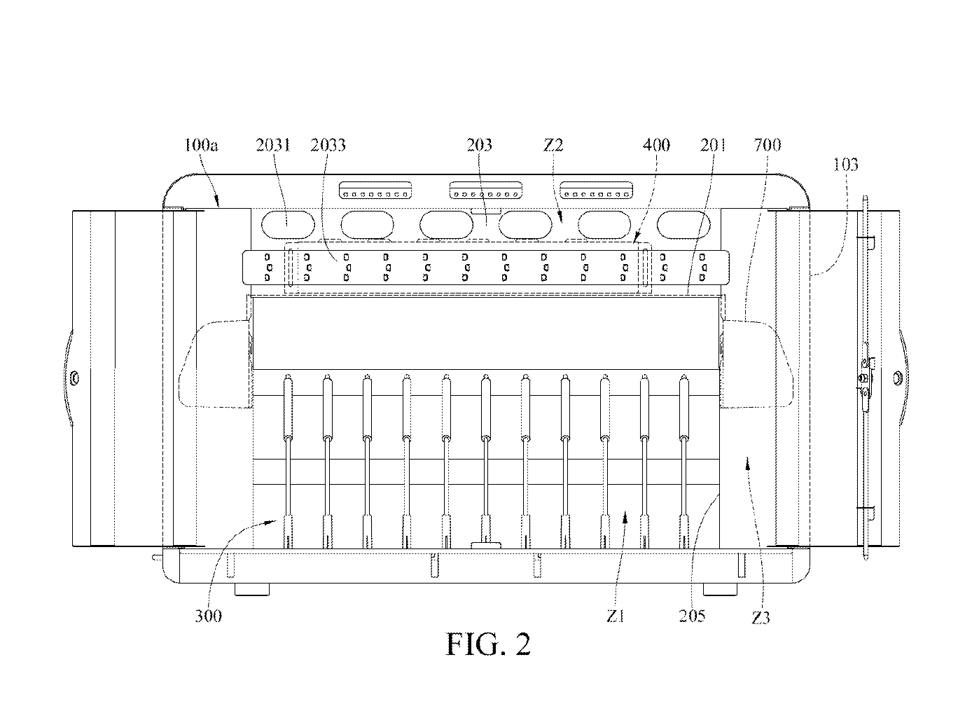

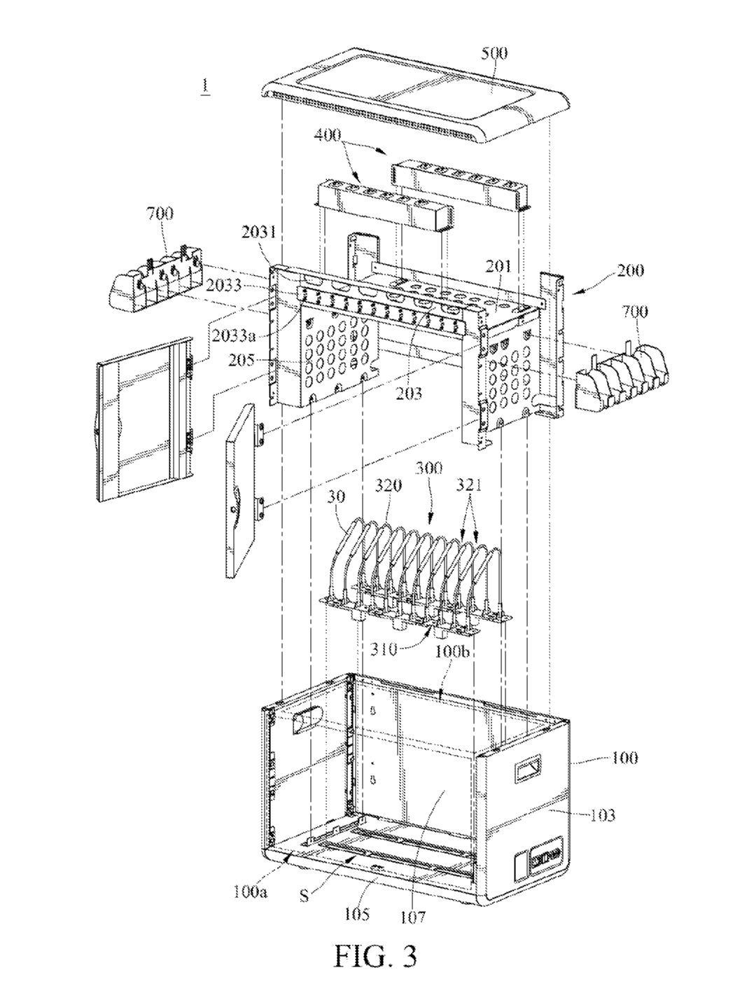

Please refer to FIGS. 1 through 3. FIG. 1 is a perspective view of a charging apparatus housing an electronic device, a power cable and a transformer according to an embodiment of the present disclosure. FIG. 2 is a front view of the charging apparatus according to the embodiment of the present disclosure. FIG. 3 is an explode view of the charging apparatus according to the embodiment of the present disclosure. This embodiment provides a charging apparatus 1 which is a charging apparatus able to charge a plurality of electronic devices 30 and store the electronic devices 30, power cables 31 and a transformers 32. It is understood by people skilled in the art that the charging apparatus 1 is able to be electrically connected to an external power for providing power to the electronic devices 30. The aforementioned electronic device 30, for example, is a smart phone, a tablet computer or a notebook computer each having the transformer. The following description will describe how the electronic devices are being charged and how the electronic devices 30, power cables 31 and transformers 32 are being stored.

In this embodiment, the charging apparatus 1 includes a case body 100, a partition module 200, a rack module 300 and a power supply component 400.

In detail, there are a first accommodation opening 100a and a second accommodation opening 100b located on two surfaces of the case body 100 that are adjacent to each other, respectively. The case body 100 includes two side plates 103, a bottom plate 105 and a rear plate 107. A direction of the first accommodation opening 100a is substantially the same as a normal direction of a surface of the rear plate 107. A direction of the second accommodation opening 100b is substantially the same as a normal direction of a surface of the bottom plate 105. The two side plates 103 are disposed on two sides of the bottom plate 105 that are opposite to each other, respectively. The two side plates 103 are disposed on two sides of the rear plate 107 that are opposite to each other, respectively. The bottom plate 105 and the rear plate 107 are connected to each other. Hence, the two side plates 103, the bottom plate 105 and the rear plate 107 form an accommodation space S therein. The partition module 200, the rack module 300 and the power supply component 400 are disposed in the accommodation space S. The first accommodation opening 100a and the second accommodation opening 100b both communicate with the accommodation space S, respectively.

As shown in FIG. 2 and FIG. 3, the partition module 200 includes a top plate 201, a front plate 203 and two side plates 205. The top plate 201, the front plate 203 and the two side plates 205 are located in the aforementioned accommodation space S. The front plate 203 which is adjacent to a side of the first accommodation opening 100a, and the top plate 201 is connected to a side of the front plate 203. The two side plates 205 are disposed on two sides of the top plate 201, respectively. Thus, the top plate 201 and the side plate 205 are able to divide the accommodation space S into a main accommodating zone Z1, a power supply zone Z2 and two sub-accommodating zones Z3. The first accommodation opening 100a communicates with the main accommodating zone Z1. The second accommodation opening 100b communicates with the power supply zone Z2. In this embodiment, the main accommodating zone Z1 is for accommodating the electronic devices 30. The power supply zone Z2 is for providing power to the electronic devices 30. The sub-accommodating zones Z3 are for accommodating or placing the transformers 32. However, the disclosure is not limited to the configurations of the main accommodating zone Z1, the power supply zone Z2 and the sub-accommodating zones Z3.

With respect to relative positions and as shown in FIG. 2, the main accommodating zone Z1 is located under the top plate 201, the power supply zone Z2 is located atop the top plate 201, and the two sub-accommodating zones Z3 are located at two sides of the main accommodating zone Z1, respectively. That is, the top plate 201 is located between the main accommodating zone Z1 and the power supply zone Z2, and the side plate 205 is located between the main accommodating zone Z1 and one of the sub-accommodating zones Z3. However, the disclosure is not limited the aforementioned relative positions of the main accommodating zone Z1, the power supply zone Z2 and the sub-accommodating zones Z3. For example, in some embodiments, the relative positions of the main accommodating zone Z1, the power supply zone Z2 and the sub-accommodating zones Z3 can be altered to be different from those of the abovementioned embodiments. Furthermore, in some embodiments, the charging apparatus 1 has one or more than one sub-accommodating zones Z3.

In this embodiment, the front plate 203 includes a plurality of slots 2031. The slots 2031 are able to communicate with the power supply zone Z2 for being penetrated by the power cables 31.

In this and some embodiments and as shown in FIG. 2 and FIG. 3, the charging apparatus 1 further includes a cable arrangement part 2033 disposed on a surface of the front plate 203. In this embodiment, the cable arrangement part 2033 is disposed on the surface of the front plate 203 which is located away from the rear plate 107 of the case body 100 and under the slots 2031. In addition, the cable arrangement part 2033 includes a plurality of clipping members 2033a for clipping the power cables 31 penetrating from the slots 2031. It is understood by people skilled in the art that any configuration of the clipping member which is able to retain or clip the power cable 31 falls within the scope of the embodiments of the disclosure.

In addition, in this embodiment, the charging apparatus 1 further includes a lid 500, two doors 600, a first locking component 610 and a second locking component 620. The lid 500 is detachably disposed on the case body 100. The lid 500 is able to cover or close the second accommodation opening 100b. Thus, users are able to cover the second accommodation opening 100b by the lid 500 when the power cable 31 is placed into the charging apparatus 1. Moreover, the two doors 600 are pivotally disposed at two ends of the case body 100 that are opposite to each other, respectively. Specifically, the two doors 600 are pivoted to two sides of the first accommodation opening 100a that are opposite to each other, respectively. Thus, users are able to close or expose the first accommodation opening 100a by rotating the two doors 600. Users are able to close the first accommodation opening 100a when the electronic device 30 is placed into the charging apparatus 1 for being charged. The first locking component 610 and the second locking component 620 are able to be locked to each other, and are disposed to the doors 600, respectively, for locking the doors 600, but the embodiment is not limited to the configuration of the locking components. In addition, the disclosure is not limited to the lid 500, the two doors 600, the first locking component 610 and the second locking component 620, which means these components are optional. For example, in some embodiments, any one of these components is able to be removed.

In this embodiment, the rack module 300 is disposed on the bottom plate 105 of the case body 100 and located within the aforementioned main accommodating zone Z1 for accommodating and housing the electronic devices 30.

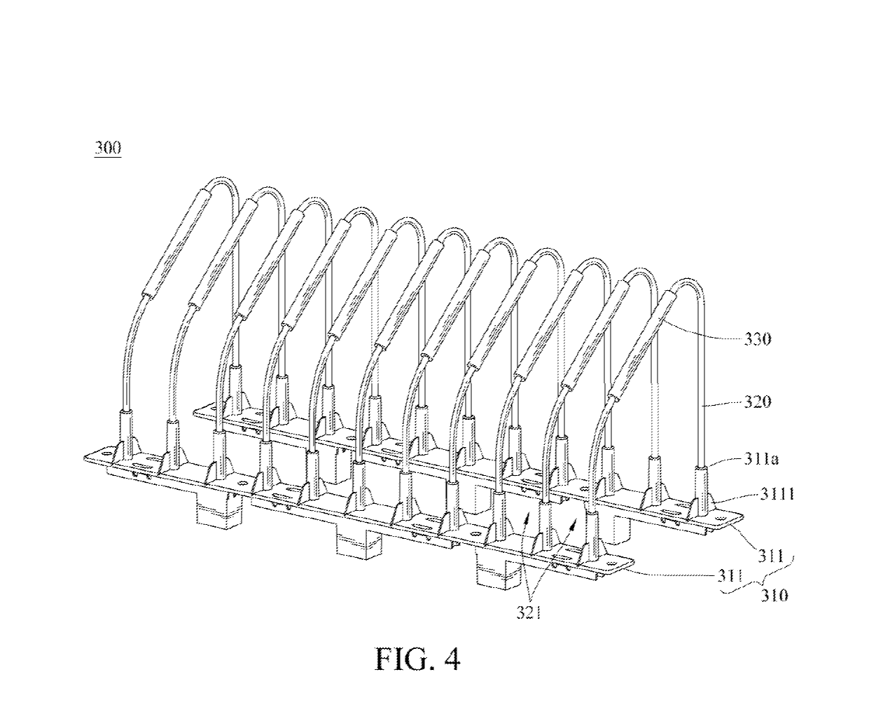

Specifically, please refer to FIG. 4, which is a schematic perspective view of a rack module according to the embodiment of the present disclosure. The rack module 300 includes a fixing seat 310, a plurality of partition members 320 and a plurality of protective members 330. The fixing seat 310 includes two fixing parts 311 that are spaced apart by a specific distance. The fixing seat 310 is detachably disposed on the case body 100, and is located in the main accommodating zone Z1 of the accommodation space S. In some embodiments, the fixing seat 310 is an integral one-piece structure. In some embodiments, the partition members 320 and the fixing seat 310 are integrated into a single unit. The partition members 320 are detachably disposed on the fixing seat 310. Furthermore, there is a housing space 321 located between any two of the partition members 320 which are adjacent to each other for accommodating and housing the electronic device 30. In this embodiment, for example, the partition members 320 are bar-shaped and the bar can be bent to connect the two fixing parts 311. In addition, the present disclosure is not limited to the quantity of the partition members 320. In some embodiments, the quantity of the partition member 320 is altered according to actual requirement, in order to alter the quantity of the housing spaces 321.

In this and some embodiments, each of the fixing parts 311 includes a plurality of hollow tubes 311a, and two ends of each of the partition members 320 are inserted into the hollow tubes 311a of the fixing parts 311, respectively, for combining with the two fixing parts 311 of the fixing seat 310.

In addition, in this and some embodiments, each of the fixing parts 311 includes ribs 3111 disposed on a periphery of each of the hollow tubes 311a, in order to enhance the strength of that the partition members 320 disposed inside the hollow tubes 311a of the fixing seat 310.

In this and some embodiments, the protective members 330 are disposed on the partition members 320, respectively, and the partition members 320 are sleeved by the protective member 330, respectively. For example, the protective members 320 are made of foam or other elastic material, e.g., rubber or sponge. Thus, when the electronic device 30 is positioned between any two of the partition members 320 adjacent to each other, the protective members 330 are able to protect the electronic device 30 as well as absorbing an external impact applying to the electronic device 30. In addition, the protective members 330 are able to prevent the electronic devices 30 from being scratched by directly contacting the partition members 320.

In this embodiment, the power supply component 400 is disposed on the aforementioned top plate 201 and located within the power supply zone Z2 for being electrically connected to the power cable 31. It is understood by people skilled in the art that the power supply component 400 is able to be electrically connected to the external power via cables in order to provide power for the power cables 31.

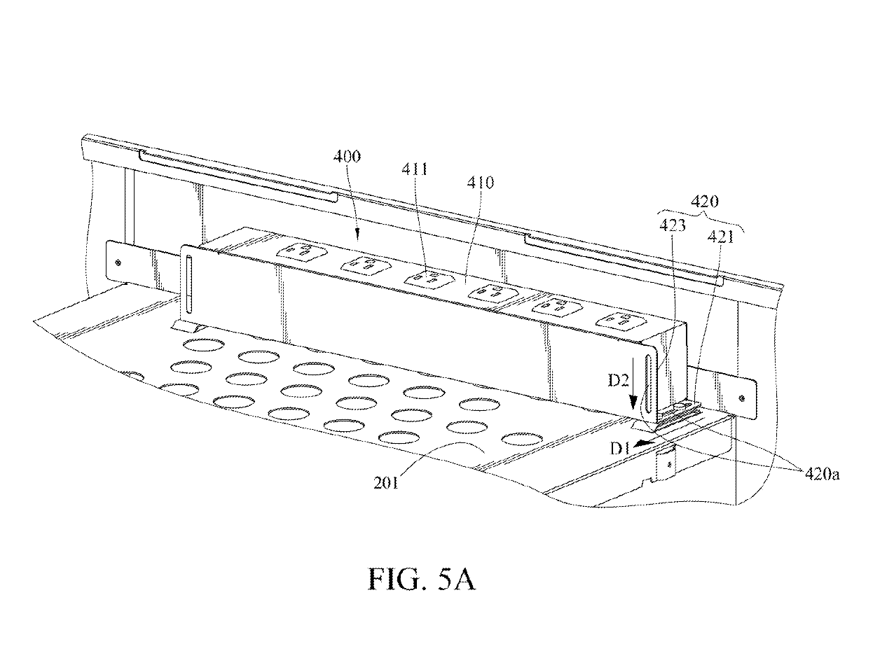

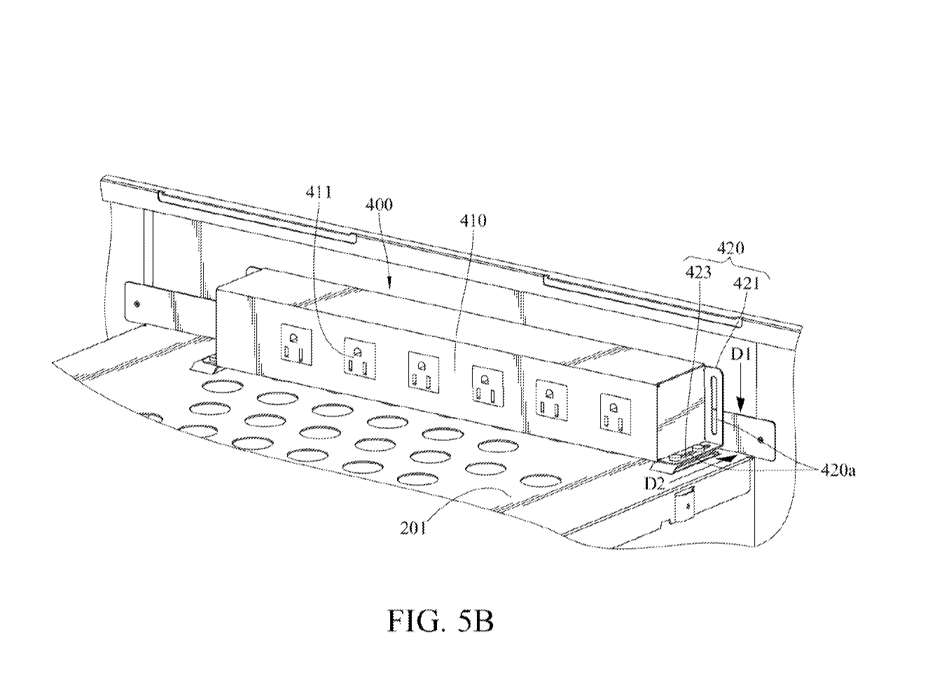

In detail, please refer to FIG. 5A and FIG. 5B. FIG. 5A is a schematic perspective view of a power supply component disposed on the charging apparatus according to the embodiment of the present disclosure. FIG. 5B is another schematic perspective view of the power supply component disposed on the charging apparatus according to the embodiment of the present disclosure. The power supply component 400 includes a power supply part 410 and two locking parts 420. There is a plurality of receptacles 411 disposed on a surface of the power supply part 410 for being plugged by the plugs of the power cables 31. The locking parts 420 are disposed at two ends of the power supply part 410 that are opposite to each other, respectively. Each of the locking parts 420 includes a first extension section 421 and a second extension section 423. An extending direction D1 of the first extension section 421 is intersected to an extending direction D2 of the second extension section 423, and the first extension section 421 and the second extension section 423 are located on two sidelines of two ends of the power supply part 410 that are adjacent to each other, respectively. Each of the first extension section 421 and the second extension section 423 includes a locking groove 420a for locking the power supply component onto the top plate 201.

Hence, users are able to lock the power supply component 400 to the top plate 201 through the locking groove 420a of the first extension section 421 or the second extension section 423 according to actual requirement. As shown in FIG. 5A, the power supply component 400 is locked on the top plate 201 through the locking groove 420a of the first extension section 421, and thus the receptacles 411 of the power supply component 400 face away from the front plate 203. As shown in FIG. 5B, the power supply component 400 is locked on the top plate 201 through the locking groove 420a of the second extension section 423, and thus the receptacles 411 of the power supply component 400 face away from the top plate 201. That is, users are able to adjust where the receptacles 411 of the power supply part 410 face, and it is convenient for users to plug and arrange the power cables in the power supply zone Z2. Thus, users are able to plug different sizes of plugs. For example, users are able to adjust the power supply component 400 to adapt different sizes of the plugs according to standards in different regions or countries.

In addition, the present disclosure is not limited to the quantity of the power supply component 400. For example, users are able to alter the quantity of the power supply component 400.

In this embodiment, as shown in FIG. 2, the two shelves 700 are detachably disposed on the side plates 205, respectively, and located in the sub-accommodating zones Z3, respectively, for accommodating the transformers 32. The shelf 700, for example, is a structure with single accommodating room or a structure with a plurality of accommodating rooms, which means specifications of the shelves 700 are optional, and are altered according to actual requirement.

An operation method of the charging apparatus 1 is described in the following description.

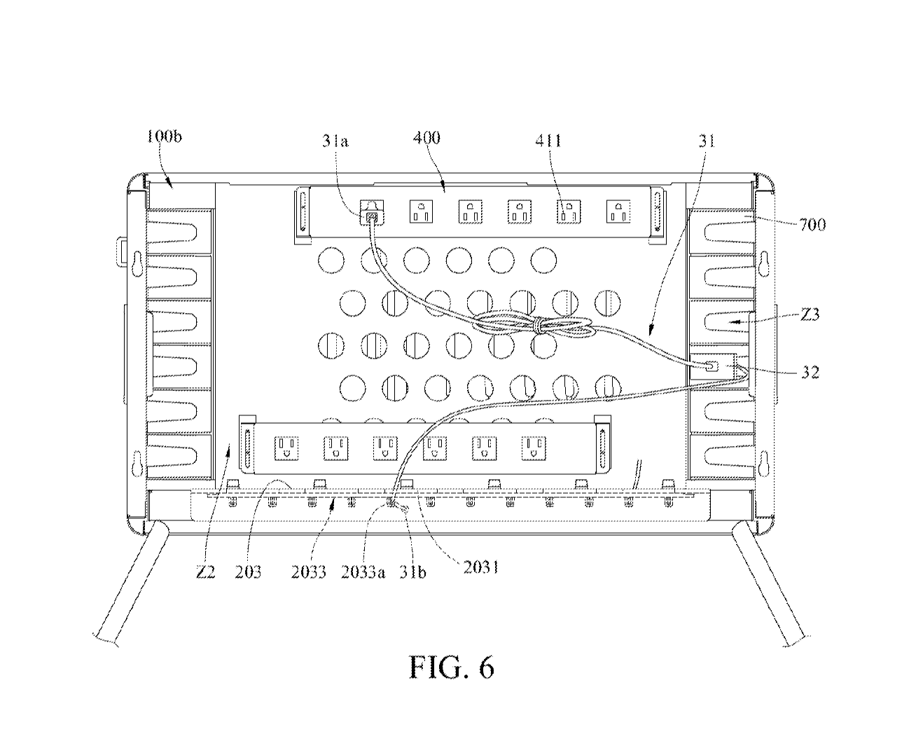

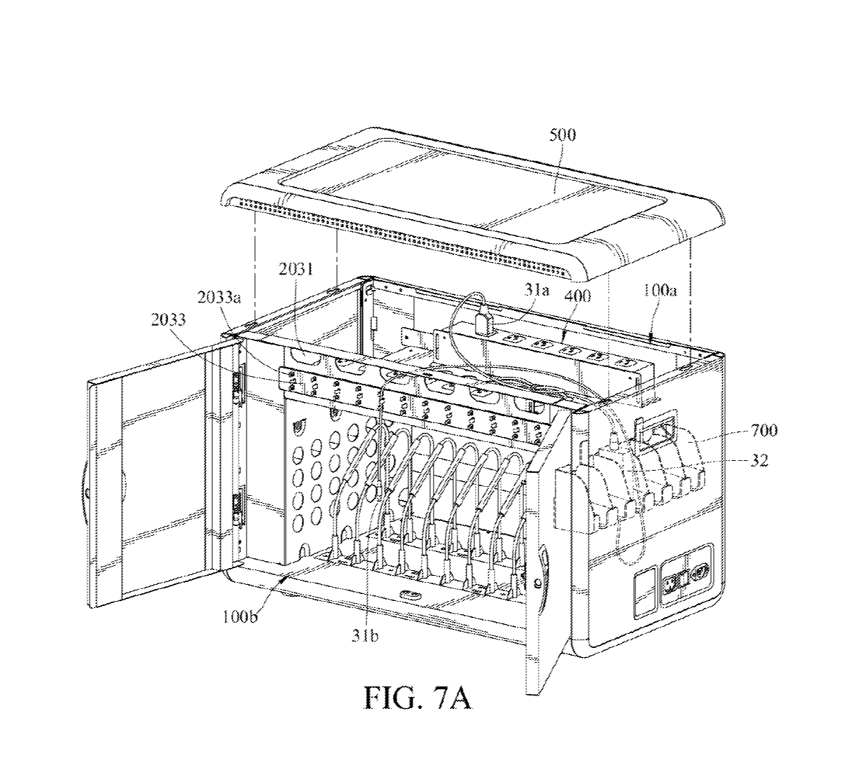

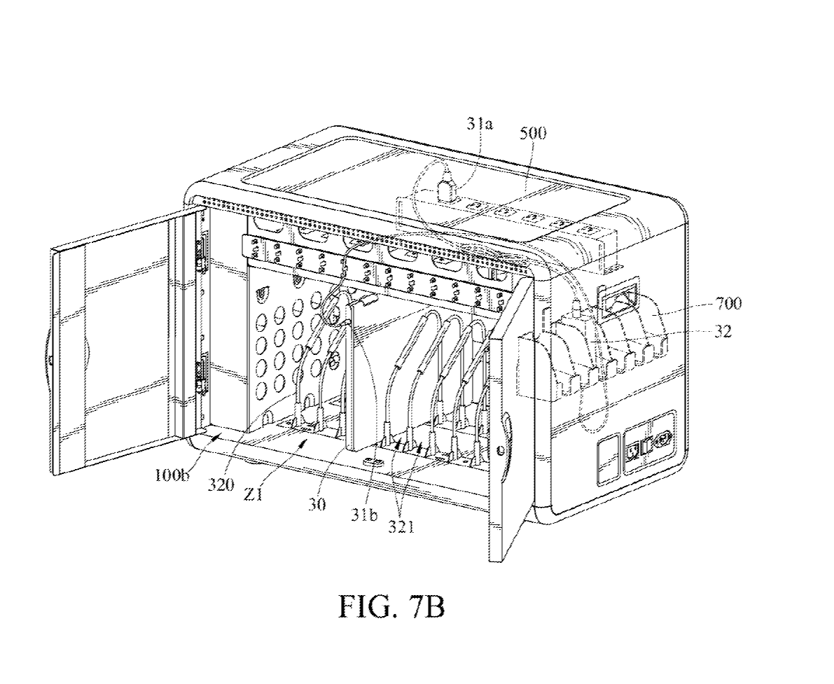

Please refer to FIGS. 6, 7A and 7B. FIG. 6 is a top view of the charging apparatus housing the power cable and the transformer according to the embodiment of the present disclosure. FIG. 7A is an exploded view of the charging apparatus housing the power cable and the transformer when a lid is lifted according to the embodiment of the present disclosure. FIG. 7B is another exploded view of the charging apparatus housing the electronic device, the power cable and the transformer according to the embodiment of the present disclosure. For purposes of clarity, FIG. 6 omits the lid 500.

As shown in FIG. 6 and FIG. 7A, users are able to plug the first plug 31a of the power cable 31a to the receptacle 411 of the power supply component 400 from the second accommodation opening 100b and place the transformer 32 of the power cable 31 into the shelf 700 within the sub-accommodating zone Z3. In addition, a second plug 31b and parts of cables of the power cable 31 are able to penetrate through the slot 2031 of the front plate 203. The parts of cables of the power cable 31, which penetrates through the slot 2031, are clipped or retained in the clipping member 2033a of the cable arrangement part 2033.

As shown in FIG. 7B, the second accommodation opening 100b is covered by the lid 500. In addition, users are able to place the electronic device 30 into the main accommodating zone Z1 of the accommodation space S via the first accommodation opening 100a. For example, users are able to place the electronic device 30 into one of the housing spaces 321 between any two of the partition members 320 adjacent to each other in the main accommodating zone Z1 and plug the second plug 31b of the power cable 31 to charge the electronic device 30.

It is understood by people skilled in the art that the power cables 31 and the transformers 32 are normally retained and stored in the power supply zone Z2 and the sub-accommodating zone Z3, respectively. Thus, users are able to charge the electronic device 30 without carrying the power cable 31 and the transformer 32 along. The users are able to charge the electronic device 30 by placing the electronic device 30 into the housing space 321 and plugging the power cable 31.

In addition, in this embodiment, because the shelves 700 are detachably disposed in the sub-accommodating zones Z3, respectively, and the specification of the shelves 700 are optional. Thus, the shelves 700 are able to adapt different sizes of the transformers 32. In some embodiments, the shelves 700 are removed, and the transformers 32 are directly disposed within the sub-accommodating zones Z3.

According to the charging apparatus as discussed above, the accommodation space of the case body is divided into the main accommodating zone, the power supply zone and the sub-accommodating zone. Specifically, the main accommodating zone includes the partition members for dividing the main accommodating zone into the plurality of housing spaces for accommodating the electronic devices. The sub-accommodating zone is for accommodating the transformers. The power supply component, which is disposed in the power supply zone, is for being electrically connected to the power cable. Hence, the electronic devices, the power cables and the transformers are disposed in the aforementioned zones, respectively in order to prevent the power cables from being tangled with each other. Furthermore it prevents the space in the charging apparatus from becoming a mess because of the unorganized transformers. In addition, in the power supply zone, users are able to adjust the direction of the power supply component to supply power in order to adapt different sizes of the plugs according to different standards.

What is claimed is:

1. A charging apparatus for charging at least one electronic device and accommodating the at least one electronic device and at least one power cable which is connected to the at least one electronic device, the power cable having at least one transformer, and the charging apparatus comprising:
a case body having an accommodation space, the accommodation space having a main accommodating zone, a power supply zone and at least one sub-accommodating zone, the power supply zone being located above the main accommodating zone, the at least one sub-accommodating zone being located on a side of the main accommodating zone, and the sub-accommodating zone being for accommodating the at least one transformer;
at least one partition member being disposed in the main accommodating zone, the main accommodating zone being divided into a plurality of housing spaces by the at least one partition member, and the plurality of housing spaces being for accommodating the at least one electronic device; and
at least one power supply component being disposed in the power supply zone for being coupled to the at least one power cable.

2. The charging apparatus according to claim 1, further comprising a partition module, the partition module comprising a top plate, a front plate and at least one side plate, the top plate being located between the power supply zone and the main accommodating zone, the front plate being connected to a side of the top plate, the at least one side plate being located between the at least one sub-accommodating zone and the main accommodating zone, and the at least one power supply component being detachably disposed on the top plate.

3. The charging apparatus according to claim 2, wherein the front plate has at least one slot communicated with the power supply zone, and the at least one power cable passes through the at least one slot.

4. The charging apparatus according to claim 3, further comprising a cable arrangement part being disposed on the front plate and being located under the at least one slot, and the cable arrangement part being for fixing the at least one power cable penetrating from the at least one slot.

5. The charging apparatus according to claim 1, further comprising a fixing seat being detachably disposed on the case body and being located in the accommodation space, and the at least one partition member being detachably disposed on the fixing seat.

6. The charging apparatus according to claim 1, wherein two surface of the case body, which are adjacent to each other, respectively has a first accommodation opening and a second accommodation opening, the first accommodation opening communicates with the main accommodating zone, the second accommodation opening communicates with the power supply zone, the at least one electronic device is for being picked out of or placed in the main accommodating zone through the first accommodation opening, and the at least one transformer is for being picked out of or placed in the main accommodating zone through the second accommodation opening.

7. The charging apparatus according to claim 6, further comprising a lid being detachably disposed on the case body, and the lid being for covering the second accommodation opening.

8. The charging apparatus according to claim 6, further comprising two doors being pivotally disposed on two ends of the case body which are opposite to each other, respectively, and the doors being for closing the first accommodation opening.

9. The charging apparatus according to claim 8, further comprising a first locking component disposed on one of the doors and a second locking component disposed on the other one of the doors, and the first locking component and the second locking being for locking the doors.

10. The charging apparatus according to claim 1, further comprising at least one shelf being detachably disposed in the at least one sub-accommodating zone, and the shelf being for accommodating the at least one transformer.

11. A power supply component for being fixed on an object and charging at least one electronic device, the power supply component comprising:
a power supply part having a plurality of receptacles; and
at least one locking part being disposed on the power supply part, the at least one locking part having a first extension section and a second extension section, an extension direction of the first extension section and an extension direction of the second extension section being intersected to each other, both the first extension section and the second extension section being located on two sidelines of two ends of the power supply part which are adjacent to each other, respectively, each of the first extension section and the second extension section having a locking groove, and the power supply component being locked to the object via the locking groove of the first extension section or the locking groove of the second extension section.

12. A rack module for being disposed on an object and accommodating at least one electronic device, the rack module comprising:
a fixing seat being detachably disposed on the object; and
a plurality of partition members being detachably disposed on the fixing seat, a housing spaces being located between the plurality of partition members, and the housing space being for accommodating the at least one electronic device.

13. The rack module according to claim 12, further comprising a plurality of protective members, and the each of the plurality of partition members being sleeved by the each of the plurality of protective members.

14. The rack module according to claim 12, wherein the fixing seat comprises two fixing parts spaced apart by a distance, and two ends of each of the plurality of partition members are respectively disposed on the fixing parts.

15. The rack module according to claim 14, wherein each of the fixing parts has at least one hollow tube, the plurality of partition members is bar-shaped, and two ends of the plurality of partition members are respectively inserted into the at least one hollow tube.

16. The rack module according to claim 15, wherein each of the fixing parts has at least one rib, and the at least one rid is disposed on a periphery of the at least one hollow tube.
